(19) United States
(12) Patent Application Publication
(10) Pub. No.: US 2025/0201542 A1
(43) Pub. Date: Jun. 19, 2025

(54) SUBSTRATE PROCESSING APPARATUS AND SUBSTRATE PROCESSING METHOD

(71) Applicant: SEMES CO., LTD., Cheonan-si (KR)

(72) Inventor: Jinhyeok KIM, Cheonan-si (KR)

(73) Assignee: SEMES CO., LTD., Cheonan-si (KR)

(21) Appl. No.: 18/981,430

(22) Filed: Dec. 13, 2024

(30) Foreign Application Priority Data
Dec. 14, 2023 (KR) 10-2023-0182147

(51) Int. Cl. H01J 37/32; G01N 30/72; H01L 21/263

(52) U.S. Cl. CPC H01J 37/32981; H01J 37/32449; H01L 21/263; G01N 30/7206; H01J 2237/24585

(57) ABSTRACT

Provided is a substrate processing apparatus including a chamber having a space where plasma is generated from a process gas mixture and a substrate is processed using the generated plasma, a gas supplier for supplying the process gas mixture to the chamber through a gas transfer line connected to a gas inlet provided in the chamber, and a gas analyzer for analyzing information about a plurality of process gases constituting the process gas mixture, outside the chamber by receiving a portion of the process gas mixture from a sample transfer line connected to the gas transfer line.

### CROSS-REFERENCE TO RELATED PATENT APPLICATION

This application claims the benefit of Korean Patent Application No. 10-2023-0182147, filed on Dec. 14, 2023, in the Korean Intellectual Property Office, the disclosure of which is incorporated herein in its entirety by reference.

### BACKGROUND OF THE INVENTION

### 1. Field of the Invention

The present invention relates to a substrate processing apparatus and a substrate processing method and, more particularly, to a substrate processing apparatus capable of analyzing process gases used for a plasma process, in a non-plasma status, and a substrate processing method using the same.

### 2. Description of the Related Art

Currently, semiconductor systems are pursuing high capacity and high functionality due to high integration of semiconductor elements and increase in size of semiconductor substrates. Because integration of more elements within a limited area is required accordingly, the semiconductor systems are being studied and developed to achieve ultra-fineness and high integration of desired patterns.

A substrate processing apparatus is an apparatus for processing a substrate by using a reaction gas in a plasma status by activating and transforming the reaction gas to a plasma status. For example, the substrate processing apparatus includes a plasma etching apparatus for etching a structure formed on a surface of a substrate, or an apparatus for forming a layer on at least one surface of the substrate through plasma chemical vapor deposition. Depending on a method of generating plasma, the plasma is divided into capacitively coupled plasma (CCP), inductively coupled plasma (ICP), electron cyclotron resonance (ECR) plasma and surface wave plasma (SWP) using microwaves, etc. For the CCP type, the reaction gas is transformed to a plasma status by an electric field formed by selectively applying high-frequency radio-frequency (RF) power to a plurality of electrodes mounted in a process chamber. For the ICP type, the reaction gas is transformed to a plasma status by a magnetic or electric field formed by applying high-frequency RF power to a coil wound outside the process chamber.

In the substrate processing apparatus, a mixture of a plurality of process gases (hereinafter referred to as a process gas mixture) may be supplied into a process chamber. The plurality of process gases may be used as reaction precursors of a plasma deposition process or as etching gases of a plasma etching process.

Components or type of a process gas used for a process, a content ratio (or mixing ratio) of a plurality of process gases constituting a process gas mixture, etc. need to be checked while processing the substrate. To this end, in general, a process gas is transformed to a plasma status in a process chamber and then is analyzed using an optical emission spectroscope (OES). When the OES is used, the process gas may be analyzed only in a status where plasma is generated.

Particularly, when a plurality of process gases are supplied together into the process chamber and when the OES is used, reaction product gases produced due to reactions between the supplied process gases or by-product gases of the reactions are also detected and thus it is not easy to verify whether the process gases are accurately supplied into the process chamber as designed.

For example, fluorocarbon-based gases such as CF₄, CHF₃, and C₄F₆ are mixed and used as process gases of a plasma etching process, and to normally perform the etching process, it needs to be verified whether each process gas flows normally or whether a content ratio or mixing ratio of the fluorocarbon-based gases in the mixture is appropriate.

However, when plasma in the process chamber is analyzed using the OES as described above, because a plurality of reaction product gases and by-product gases are included in the plasma, it is not easy to check whether the process gases are normal.

### SUMMARY OF THE INVENTION

The present invention provides a substrate processing apparatus capable of accurately analyzing information about process gases, e.g., information indicating whether process gases used to process a substrate by using plasma are normally flowing or information indicating whether a mixing ratio of a plurality of process gases constituting a process gas mixture is normal, in a non-plasma status where plasma is not generated, and of accurately controlling the supply of the process gases based on the analysis result, and a substrate processing method using the same. However, the above description is an example, and the scope of the present invention is not limited thereto.

According to an aspect of the present invention, there is provided a substrate processing apparatus including a chamber having a space where plasma is generated from a process gas mixture and a substrate is processed using the generated plasma, a gas supplier for supplying the process gas mixture to the chamber through a gas transfer line connected to a gas inlet provided in the chamber, and a gas analyzer for analyzing information about a plurality of process gases constituting the process gas mixture, outside the chamber by receiving a portion of the process gas mixture from a sample transfer line connected to the gas transfer line.

The gas analyzer may include a gas chromatograph and a mass spectrometer.

The gas analyzer may be disposed in such a manner that the process gas mixture received through the sample transfer line is first inserted into the gas chromatograph and that gases discharged from the gas chromatograph are inserted into the mass spectrometer.

The gas chromatograph may separate the plurality of process gases constituting the inserted process gas mixture by type, and insert the plurality of separated process gases into the mass spectrometer.

The mass spectrometer may include an ionizer for ionizing the inserted process gases, a mass filter for separating ions based on mass-to-charge (m/z) ratios, and a detector for detecting information about the process gases based on the mass-to-charge ratios.

The information about the plurality of process gases may include types of the process gases and a mixing ratio of the process gases in the process gas mixture.

The substrate processing apparatus may further include a controller for receiving the detected information about the plurality of process gases from the gas analyzer, and comparing the received information with pre-stored process gas information to determine whether processing of the substrate by the process gas mixture is appropriate.

The controller may control the supply of the process gas mixture from the gas supplier to the chamber based on a result of comparing the received information with the pre-stored process gas information.

The controller may receive types of the process gases or a mixing ratio of the process gases in the process gas mixture as the information about the process gases, and give a control to cut off the supply of the process gas mixture from the gas supplier to the chamber based on the received information.

The controller may receive a mixing ratio of the process gases in the process gas mixture as the information about the process gases, and control a flow ratio between the plurality of process gases constituting the process gas mixture, based on the received information.

The space where the substrate is processed may be a space where a process of plasma-etching a structure formed on at least one surface of the substrate or a process of forming a layer on at least one surface of the substrate through plasma chemical vapor deposition is performed.

The process gases may include one or more of hydrocarbon-based gases and fluorocarbon-based gases, and further include an inert gas.

The process gases may include one or more of C₄F₆, C₄F₈, CF₄, CHF₃, CH₃F, CH₄, and C₂H₂.

According to another aspect of the present invention, there is provided a substrate processing method for processing a substrate by using plasma generated from a process gas mixture in a chamber, the substrate processing method including supplying the process gas mixture into the chamber, and analyzing information about a plurality of process gases constituting the process gas mixture, outside the chamber by receiving a portion of the process gas mixture, wherein the information about the plurality of process gases includes types of the process gases and a mixing ratio of the process gases in the process gas mixture.

The analyzing of the information about the plurality of process gases may include separating the plurality of process gases constituting the received process gas mixture by type, and ionizing the plurality of separated process gases, separating ions based on mass-to-charge (m/z) ratios, and detecting information about the plurality of process gases.

The substrate processing method may further include comparing the analyzed information about the plurality of process gases with pre-stored process gas information to determine whether processing of the substrate by the process gas mixture is appropriate, after the analyzing of the information about the plurality of process gases.

The substrate processing method may further include cutting off the supply of the process gas mixture into the chamber, when it is determined that processing of the substrate is not appropriate.

The substrate processing method may further include controlling a flow ratio between the plurality of process gases constituting the process gas mixture, based on the information about the plurality of process gases, when it is determined that processing of the substrate is not appropriate.

The substrate processing method may be a process of plasma-etching a structure formed on at least one surface of the substrate or a process of forming a layer on at least one surface of the substrate through plasma chemical vapor deposition.

According to another aspect of the present invention, there is provided a substrate processing apparatus including a chamber having a space where plasma is generated from a process gas mixture and a substrate is processed using the generated plasma, a gas supplier for supplying the process gas mixture to the chamber through a gas transfer line connected to a gas inlet provided in the chamber, a gas analyzer for analyzing information about a plurality of process gases constituting the process gas mixture, outside the chamber by receiving a portion of the process gas mixture from a sample transfer line connected to the gas transfer line, and a controller for receiving the detected information about the plurality of process gases from the gas analyzer, and comparing the received information with pre-stored process gas information to determine whether processing of the substrate by the process gas mixture is appropriate, wherein the space where the substrate is processed is a space where a process of plasma-etching a structure formed on at least one surface of the substrate or a process of forming a layer on at least one surface of the substrate through plasma chemical vapor deposition is performed, wherein the gas analyzer includes a gas chromatograph and a mass spectrometer, and wherein the controller controls the supply of the process gas mixture from the gas supplier to the chamber based on a result of comparing the received information with the pre-stored process gas information.

### BRIEF DESCRIPTION OF THE DRAWINGS

The above and other features and advantages of the present invention will become more apparent by describing in detail embodiments thereof with reference to the attached drawings in which:

FIG. 1 is a schematic view of a substrate processing apparatus according to an embodiment of the present invention;

FIG. 2 is a detailed view of a gas supplier and a gas analyzer illustrated in FIG. 1;

FIG. 3 is a schematic view of a controller connected to the gas supplier and the gas analyzer illustrated in FIG. 2; and

FIG. 4 is a flowchart of a substrate processing method according to an embodiment of the present invention.

### DETAILED DESCRIPTION OF THE INVENTION

Hereinafter, the present invention will be described in detail by explaining embodiments of the invention with reference to the attached drawings.

The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, the thicknesses or sizes of layers are exaggerated for clarity and convenience of explanation.

The terminology used herein is for the purpose of describing particular embodiments and is not intended to limit the invention. As used herein, the singular forms “a”, “an”, and “the” are intended to include the plural forms as well, unless the context clearly indicates otherwise. It will be further understood that the terms “comprises” and/or “comprising”, when used in this specification, specify the presence of stated features, integers, steps, operations, elements, components, and/or groups thereof, but do not preclude the presence or addition of one or more other features, integers, steps, operations, elements, components, and/or groups thereof.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, the embodiments of the invention should not be construed as limited to the particular shapes of regions illustrated herein, but are to include deviations in shapes that result, for example, from manufacturing.

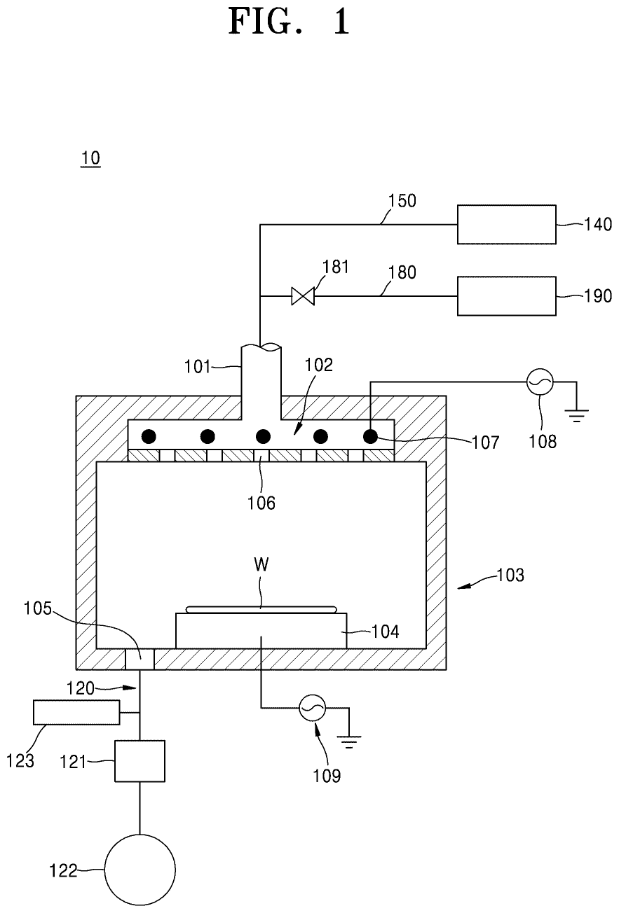

FIG. 1 is a schematic view of a substrate processing apparatus 10 according to an embodiment of the present invention, and the substrate processing apparatus 10 is a plasma etching apparatus using inductively coupled plasma (ICP). The substrate processing apparatus 10 of FIG. 1 is an example, and a substrate processing apparatus according to the present invention is not limited to the substrate processing apparatus 10 of FIG. 1, and may be any apparatus for processing a substrate by using a plasma process, e.g., an etching apparatus for generating another type of plasma or a deposition apparatus for performing plasma chemical vapor deposition.

Referring to FIG. 1, the substrate processing apparatus 10 includes a chamber 103 having a space where plasma is generated. A substrate supporter 104 is included in the chamber 103. The substrate supporter 104 may be located at the bottom of the chamber 103 to support a substrate W. The substrate W may include, for example, a silicon wafer used to manufacture semiconductor devices.

A gas supplier 140 is a system for supplying a plurality of process gases required for a plasma process, into the chamber 103 through a gas transfer line 150 connected to a gas inlet 101 provided on the chamber 103. The process gases required for the plasma process may be, for example, etching gases required for a plasma etching process. The process gases may further include a carrier gas for carrying the etching gases. A process gas mixture may be supplied from the gas supplier 140 into the chamber 103 along the gas transfer line 150 through the gas inlet 101.

An additional gas transfer line 180 is coupled to the gas transfer line 150 before the process gas mixture is inserted into the chamber 103 through the gas inlet 101. A portion of the process gas mixture transferred through the gas transfer line 150 is not inserted into the chamber 103 and transferred to a gas analyzer 190 as a sample gas for gas analysis. The gas transfer line 180 through which the sample gas is transferred is referred to as a sample transfer line 180. A valve 181 is mounted on the sample transfer line 180, and the transfer of the sample gas is controlled based on an on/off state of the valve 181. By operation of the valve 181 mounted on the sample transfer line 180, the process gas mixture flowing toward the chamber 103 may be moved to the gas analyzer 190 to analyze process gases constituting the process gas mixture.

The gas analyzer 190 may receive the process gas mixture, separate the process gas mixture into individual process gases, and perform qualitative analysis and quantitative analysis on the separated process gases.

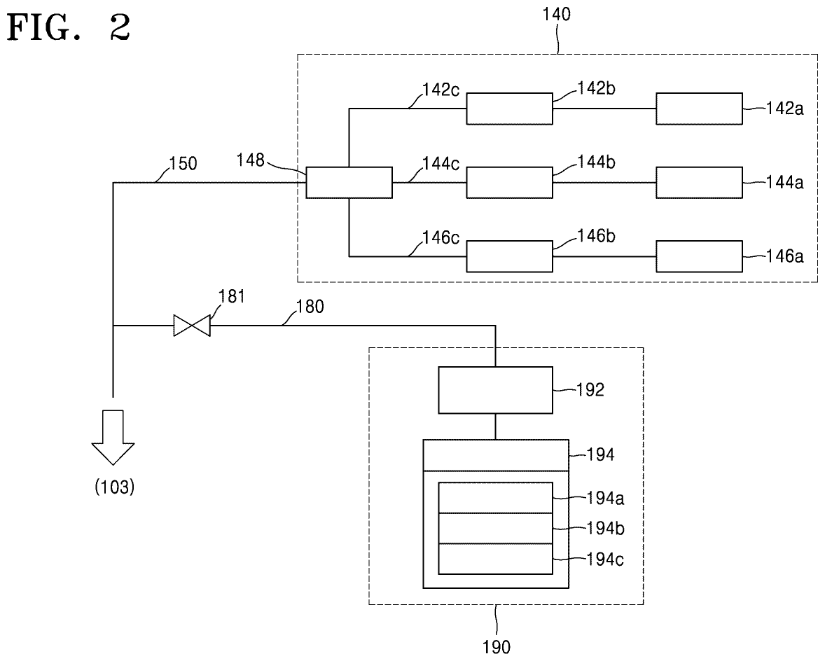

The gas supplier 140 and the gas analyzer 190 will be described in detail below with reference to FIG. 2.

A gas injector 102 is a structure provided with a plurality of injection holes 106 through which a process gas supplied from the gas supplier 140 to the chamber 103 through the gas inlet 101 may pass, to uniformly supply the process gas onto the substrate W, and is disposed above the substrate W.

To generate plasma from the process gas supplied into the chamber 103, a spiral antenna 107 for supplying power is disposed at the top of the chamber 103. A first high-frequency power source 108 is connected to the antenna 107. The first high-frequency power source 108 includes a radio-frequency (RF) power source. After the process gas is supplied into the chamber 103, when high-frequency power is applied from the first high-frequency power source 108 to the antenna 107, electromagnetic waves generated from the antenna 107 are supplied into the chamber 103 to excite the process gas to a plasma status.

The substrate supporter 104 may serve to adsorb or release the substrate W onto or from a dielectric surface by controlling electrostatic force generated due to dielectric polarization by electrodes provided therein. To apply a negative bias to the substrate W, a second high-frequency power source 109 for applying high-frequency power may be connected to the substrate supporter 104. However, the substrate W is not limited thereto, and may also be held by a mechanical clamp, a vacuum chuck, or the like.

The substrate processing apparatus 10 includes a vent hole 105 provided in a portion of the chamber 103 to discharge internal gas, and a vent line 120 connected to the vent hole 105 and having an automatic pressure controller (APC) valve 121 mounted thereon. A pressure sensor 123 for measuring a pressure inside the chamber 103 is mounted on the vent line 120. The vent line 120 may be connected to a vacuum pump 122 to serve as a path through which by-products produced in the chamber 103 are discharged to the outside of the chamber 103, or to form a vacuum in the internal space of the chamber 103.

The APC valve 121 is a valve for adjusting the pressure inside the chamber 103, and the pressure inside the chamber 103 is adjusted by controlling the opening or closing of the APC valve 121 based on the pressure inside the chamber 103 measured by the pressure sensor 123 while the vacuum pump 122 is operating.

FIG. 2 is a detailed view of the gas supplier 140 and the gas analyzer 190 illustrated in FIG. 1.

Referring to FIG. 2, the gas supplier 140 includes gas storages 142a, 144a, and 146a, gas transfer lines 142c, 144c, and 146c for transferring process gases from the gas storages 142a, 144a, and 146a to the chamber 103, and mass flow controllers (MFCs) 142b, 144b, and 146b for controlling flow rates of the process gases flowing through the gas transfer lines 142c, 144c, and 146c. The process gases transferred from the gas storages 142a, 144a, and 146a through the gas transfer lines 142c, 144c, and 146c are inserted into a mixer 148 and mixed into a process gas mixture, and then transferred through the gas transfer line 150 connected to the gas inlet 101, and inserted into the chamber 103 as indicated by an arrow (see FIG. 1).

The gas storages 142a, 144a, and 146a store the process gases used for plasma-etching, and the process gases include compound gases each consisting of a plurality of elements. The process gases may further include a carrier gas for carrying the compound gases. The process gases may further include an inert gas. The compound gases may include hydrocarbon-based gases or fluorocarbon-based gases. The hydrocarbon-based process gases may include one or more of CH₄ and C₂H₂, and the fluorocarbon-based process gases may include one or more of C₄F₆, C₄F₈, CF₄, CHF₃, and CH₃F.

Referring to FIG. 2, the gas analyzer 190 includes a gas chromatograph 192 and a mass spectrometer 194. When the valve 181 is in an on state, the process gas mixture flows into the sample transfer line 180 connected to the gas transfer line 150, and then is transferred and inserted into the gas chromatograph 192 of the gas analyzer 190. The gas chromatograph 192 may separate a plurality of process gases constituting the process gas mixture.

The gas chromatograph 192 includes a column with a stationary phase, and the process gas mixture passes through the column with the stationary phase. The process gases constituting the process gas mixture are brought into contact with the stationary phase to repeat adsorption and distribution. In this case, the process gases of the process gas mixture move through the column at different speeds due to different distribution coefficients with the stationary phase, and the difference in speed through the column may be used to separate the process gases from each other. The gas chromatograph 192 is well known in the field of material analysis, and thus a detailed description thereof is not provided herein.

The process gases separated by the gas chromatograph 192 are discharged and then inserted into the mass spectrometer 194.

The mass spectrometer 194 ionizes the process gases separated by the gas chromatograph 192, and then calculates mass spectra to perform qualitative analysis and quantitative analysis on the process gases. The qualitative analysis is to find out the types of materials of the process gases, and the quantitative analysis is to find out a relative content ratio (or mixing ratio) of the process gases in the process gas mixture.

The mass spectrometer 194 includes an ionizer 194a for ionizing the inserted process gases, a mass filter 194b for separating ions based on mass-to-charge (m/z) ratios, and a detector 194c for detecting information about the process gases based on the m/z ratios. The mass spectrometer 194 is well known in the field of material analysis, and thus a detailed description thereof is not provided herein.

The mass spectrometer 194 may detect which material each of the process gases separated by the gas chromatograph 192 is. In addition, the content ratio (or mixing ratio) of the process gases in the process gas mixture may be obtained based on the analysis results of the process gases.

Using the gas analyzer 190 of the present invention, the types of a plurality of process gases constituting the process gas mixture may be detected outside the chamber 103 by using a portion of the process gas mixture as a sample before the process gas mixture is inserted into the chamber 103 to process the substrate W. In addition, a mixing ratio of the process gases in the process gas mixture may be detected. The above analysis results may be used to determine in real time whether the process gases are normally supplied as originally designed.

According to the present invention, unlike existing gas analysis methods, the process gases do not need to be inserted into the chamber 103 and transformed into plasma in order to analyze the process gases, and the process gases may be accurately analyzed because various by-products gases are not produced due to reaction between the process gases in the chamber 103.

According to an embodiment of the present invention, the substrate processing apparatus 10 may further include a controller 170 for receiving the detected information about the plurality of process gases from the gas analyzer 190, comparing the received information with pre-stored process gas information to determine whether processing of the substrate W by the process gas mixture is appropriate, and controlling the supply of the process gas mixture from the gas supplier 140 to the chamber 103 based on the comparison result.

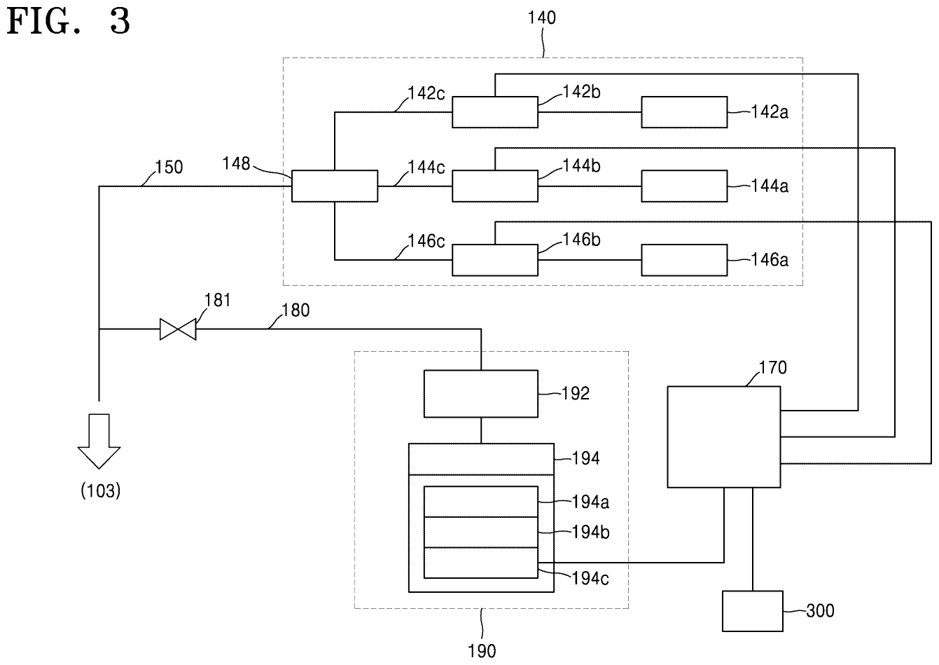

The controller 170 is illustrated in FIG. 3 in addition to the gas supplier 140 and the gas analyzer 190 illustrated in FIG. 2. Referring to FIG. 3, the controller 170 receives the analyzed information about the process gases from the mass spectrometer 194. For example, the detector 194c of the mass spectrometer 194 may transmit the detected information about the process gases to the controller 170. The controller 170 is connected to a storage 300 which pre-stores information about process gases used for a plasma process.

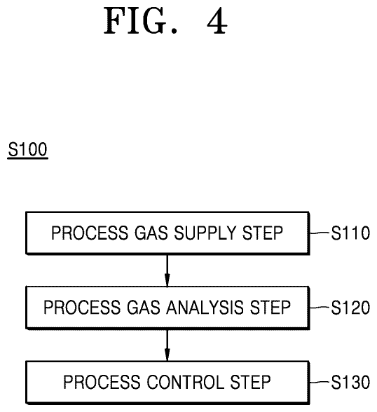

FIG. 4 is a flowchart of a substrate processing method S100 according to an embodiment of the present invention. Referring to FIG. 4, the substrate processing method S100 according to an embodiment of the present invention includes a process gas mixture supply step S110, a process gas mixture analysis step S120, and a process control step S130.

The process gas mixture supply step S110 and the process gas mixture analysis step S120 are already described above, and thus the process control step S130 will now be described in detail.

The detector 194c of the mass spectrometer 194 transmits the detected analysis information about the process gases to the controller 170. The controller 170 may receive the information, retrieve conditions related to process gases used to process the substrate W, from the storage 300, and then compare the conditions with the information received from the mass spectrometer 194. Through the comparison, it is determined whether processing of the substrate W by the process gas mixture is appropriate.

For example, the compared information includes the types of the process gases and the mixing ratio of the process gases. According to the comparison result, when the process gases supplied to the chamber 103 to process the substrate W are different from process gases in a process recipe stored in the storage 300, it may be determined that processing of the substrate W is not appropriate. Alternatively, when the mixing ratio of the process gases constituting the process gas mixture is different from a mixing ratio in the process recipe, it may be determined that processing of the substrate W is not appropriate. When it is determined that processing of the substrate W is not appropriate, the controller 170 may respond in real time by controlling the gas supplier 140.

For example, when it is determined that the substrate W may not be processed as intended because the types of the inserted process gases are different from the originally designed types or the mixing ratio between the process gases is significantly different, the controller 170 may cut off the supply of the process gas mixture to the chamber 103 by controlling the gas supplier 140. Referring to FIG. 3, the controller 170 may cut off the supply of the process gas mixture to the chamber 103 by applying electrical signals to the MFCs 142b, 144b, and 146b to block the transfer of the process gases. In addition, the controller 170 may form a vacuum atmosphere inside the chamber 103 again by continuously operating the vacuum pump 122 connected to the vent hole 105 of the chamber 103 to discharge the process gas mixture remaining in the chamber 103 through the vent hole 105.

As another example, the controller 170 may give a control for modifying the difference in mixing ratio of the process gases constituting the process gas mixture in real time while maintaining the supply of the process gas mixture to the chamber 103.

Referring to FIG. 3, for example, the controller 170 may retrieve the information about the process gases received from the mass spectrometer 194, from the storage 300, and then determine the difference in mixing ratio between the process gases is different from the mixing ratio designed by a process recipe and thus needs to be modified. In this case, the controller 170 may control the mixing ratio between the process gases in the mixer 148 by individually controlling flow rates of the process gases inserted into the mixer 148.

For example, the controller 170 may control the MFCs 142b, 144b, and 146b to control the flow rates of the process gases passing through the MFCs 142b, 144b, and 146b such that the mixing ratio between the process gases is identical to a value in a preset process recipe. In this case, the processing of the substrate W in the chamber 103 is not interrupted, and the mixing ratio between the process gases inserted while processing the substrate W is modified to process the substrate W. In this manner, the process gases may be controlled in real time to be provided into the chamber 103 under pre-designed process conditions.

According to the afore-described embodiments of the present invention, normal supply of process gases may be checked in a non-plasma status by accurately analyzing process gases used to process a substrate by using plasma. In addition, an excellent-quality plasma process may be stably performed by controlling process gas supply amounts or process conditions about a process gas flow ratio based on the above-described analysis. However, the scope of the present invention is not limited to the above effects.

While the present invention has been particularly shown and described with reference to embodiments thereof, it will be understood by one of ordinary skill in the art that various changes in form and details may be made therein without departing from the scope of the present invention as defined by the following claims.

What is claimed is:

1. A substrate processing apparatus comprising:
a chamber having a space where plasma is generated from a process gas mixture and a substrate is processed using the generated plasma;
a gas supplier for supplying the process gas mixture to the chamber through a gas transfer line connected to a gas inlet provided in the chamber; and
a gas analyzer for analyzing information about a plurality of process gases constituting the process gas mixture, outside the chamber by receiving a portion of the process gas mixture from a sample transfer line connected to the gas transfer line.

2. The substrate processing apparatus of claim 1, wherein the gas analyzer comprises a gas chromatograph and a mass spectrometer.

3. The substrate processing apparatus of claim 2, wherein the gas analyzer is disposed in such a manner that the process gas mixture received through the sample transfer line is first inserted into the gas chromatograph and that gases discharged from the gas chromatograph are inserted into the mass spectrometer.

4. The substrate processing apparatus of claim 2, wherein the gas chromatograph separates the plurality of process gases constituting the inserted process gas mixture by type, and inserts the plurality of separated process gases into the mass spectrometer.

5. The substrate processing apparatus of claim 4, wherein the mass spectrometer comprises:
an ionizer for ionizing the inserted process gases;
a mass filter for separating ions based on mass-to-charge (m/z) ratios; and
a detector for detecting information about the process gases based on the mass-to-charge ratios.

6. The substrate processing apparatus of claim 1, wherein the information about the plurality of process gases comprises types of the process gases and a mixing ratio of the process gases in the process gas mixture.

7. The substrate processing apparatus of claim 1, further comprising a controller for receiving the detected information about the plurality of process gases from the gas analyzer, and comparing the received information with pre-stored process gas information to determine whether processing of the substrate by the process gas mixture is appropriate.

8. The substrate processing apparatus of claim 7, wherein the controller controls the supply of the process gas mixture from the gas supplier to the chamber based on a result of comparing the received information with the pre-stored process gas information.

9. The substrate processing apparatus of claim 8, wherein the controller receives types of the process gases or a mixing ratio of the process gases in the process gas mixture as the information about the process gases, and gives a control to cut off the supply of the process gas mixture from the gas supplier to the chamber based on the received information.

10. The substrate processing apparatus of claim 8, wherein the controller receives a mixing ratio of the process gases in the process gas mixture as the information about the process gases, and controls a flow ratio between the plurality of process gases constituting the process gas mixture, based on the received information.

11. The substrate processing apparatus of claim 1, wherein the space where the substrate is processed is a space where a process of plasma-etching a structure formed on at least one surface of the substrate or a process of forming a layer on at least one surface of the substrate through plasma chemical vapor deposition is performed.

12. The substrate processing apparatus of claim 1, wherein the process gases comprise one or more of hydrocarbon-based gases and fluorocarbon-based gases, and further comprise an inert gas.

13. The substrate processing apparatus of claim 12, wherein the process gases comprise one or more of C₄F₆, C₄F₈, CF₄, CHF₃, CH₃F, CH₄, and C₂H₂.

14. A substrate processing method for processing a substrate by using plasma generated from a process gas mixture in a chamber, the substrate processing method comprising:
supplying the process gas mixture into the chamber; and
analyzing information about a plurality of process gases constituting the process gas mixture, outside the chamber by receiving a portion of the process gas mixture,
wherein the information about the plurality of process gases comprises types of the process gases and a mixing ratio of the process gases in the process gas mixture.

15. The substrate processing method of claim 14, wherein the analyzing of the information about the plurality of process gases comprises:
separating the plurality of process gases constituting the received process gas mixture by type; and
ionizing the plurality of separated process gases, separating ions based on mass-to-charge (m/z) ratios, and detecting information about the plurality of process gases.

16. The substrate processing method of claim 14, further comprising comparing the analyzed information about the plurality of process gases with pre-stored process gas information to determine whether processing of the substrate by the process gas mixture is appropriate, after the analyzing of the information about the plurality of process gases.

17. The substrate processing method of claim 16, further comprising cutting off the supply of the process gas mixture into the chamber, when it is determined that processing of the substrate is not appropriate.

18. The substrate processing method of claim 16, further comprising controlling a flow ratio between the plurality of process gases constituting the process gas mixture, based on the information about the plurality of process gases, when it is determined that processing of the substrate is not appropriate.

19. The substrate processing method of claim 14, wherein the substrate processing method is a process of plasma-etching a structure formed on at least one surface of the substrate or a process of forming a layer on at least one surface of the substrate through plasma chemical vapor deposition.

20. A substrate processing apparatus comprising:
a chamber having a space where plasma is generated from a process gas mixture and a substrate is processed using the generated plasma;
a gas supplier for supplying the process gas mixture to the chamber through a gas transfer line connected to a gas inlet provided in the chamber;
a gas analyzer for analyzing information about a plurality of process gases constituting the process gas mixture, outside the chamber by receiving a portion of the process gas mixture from a sample transfer line connected to the gas transfer line; and
a controller for receiving the detected information about the plurality of process gases from the gas analyzer, and comparing the received information with pre-stored process gas information to determine whether processing of the substrate by the process gas mixture is appropriate,
wherein the space where the substrate is processed is a space where a process of plasma-etching a structure formed on at least one surface of the substrate or a process of forming a layer on at least one surface of the substrate through plasma chemical vapor deposition is performed,
wherein the gas analyzer comprises a gas chromatograph and a mass spectrometer, and
wherein the controller controls the supply of the process gas mixture from the gas supplier to the chamber based on a result of comparing the received information with the pre-stored process gas information.
